(19) United States
(12) Patent Application Publication
(10) Pub. No.: US 2021/0180177 A1
(43) Pub. Date: Jun. 17, 2021

(54) METHOD FOR PREPARING BACTERICIDAL FILM HAVING SILICON NITRIDE BINDING LAYER ON PLASTIC

(71) Applicant: Fook Chi Mak, Hong Kong (CN)

(72) Inventor: Fook Chi Mak, Hong Kong (CN)

(21) Appl. No.: 16/903,870

(22) Filed: Jun. 17, 2020

(30) Foreign Application Priority Data
Dec. 17, 2019 (CN) 2019113039568

(51) Int. Cl. C23C 14/20; C23C 14/06; C23C 14/34; C23C 14/02

(52) U.S. Cl. CPC C23C 14/20; C23C 14/021; C23C 14/34; C23C 14/0652

(57) ABSTRACT

A method for preparing a bactericidal film having a silicon nitride binding layer on plastic, wherein the whole process does not need high temperature, and the film layers are plated without damaging the plastic. A binding film layer is plated using a silicon target and nitrogen, and a carrier layer is plated using acetylene gas. A silver target is initiated to allow silver ions to be uniformly distributed to form a bactericidal film layer. The workpiece is hung on the hanging rack during the plating process, which allows the rotation and revolution of the workpiece to be simultaneously achieved, thus realizing a uniform plating during the target's sputtering while avoiding damage to the workpiece due to local high temperature. The present disclosure remains the appearance and various properties of plastic, achieves an ideal bactericidal effect, a convenient preparation and a low investment of equipment, and has a wide application range.

### TECHNICAL FIELD

This disclosure generally relates to the technical field of vacuum plating, and more particularly, to a method for preparing a bactericidal film having a silicon nitride binding layer on plastic.

### BACKGROUND

Plastic products are widely used in our daily lives due to their easy processing and long life-span. Many of them such as household products, children's toys, handrails on vehicles, computers and mobile phones are frequently used and in direct contact with people. These plastic products inevitably carry a large number of bacteria. A scientific research shows that the bacteria carried on a mobile phone used every day is much more than that on a flushing toilet. Thus, a method capable of protecting plastic products from bacteria is particularly wanted.

### SUMMARY

The purpose of the present disclosure is to provide a method for preparing a bactericidal film having a silicon nitride binding layer on plastic, which effectively protects the furnace body from being damaged by oxygen introduced into the furnace for forming a silicon oxide bactericidal layer in the prior art, and significantly improves the bactericidal ability of the plated film by preventing the generation of silver oxide caused by a large amount of residual oxygen in the furnace during the silver target's sputtering.

To achieve the above purpose, the present disclosure adopts the following technical solution: a method for preparing a bactericidal film having a silicon nitride binding layer on plastic, comprising the steps of:

Preprocessing: cleansing a workpiece and blow-drying at a low temperature;

Vacuum processing: hanging the preprocessed workpiece on a hanging rack, and placing into a vacuum furnace; supplying a bias voltage to the metal hanging rack, and vacuuming the furnace to a vacuum degree of 5.0×10⁻³ Pa; initiating a rotating disc, thus making the workpiece rotate on the hanging rack, and simultaneously making the hanging rack rotate within the vacuum furnace;

Plating a binding film layer: switching-on a power supply and regulating the voltage to 30-40V, wherein the duty ratio is 20-30%; introducing argon, thereby enabling the vacuum degree to reach 25×10⁻² Pa; subsequently, initiating a silicon sputtering target, and introducing nitrogen, which enables the vacuum degree to reach 35×10⁻² Pa, thus forming a silicon nitride binding film layer on the surface of the workpiece;

Plating a carrier layer: keeping the silicon target sputtering, turning-off the nitrogen, reducing the flow of argon, and introducing acetylene gas, thus forming a silicon carbide carrier layer on the surface of the workpiece;

Plating a bactericidal film layer: keeping the silicon target sputtering, continuously introducing acetylene gas, and simultaneously initiating a silver sputtering target, thus forming a bactericidal film layer of silicon carbide and silver on the surface of the workpiece;

Completing the film plating: stopping the silicon target and the silver target first, and then turning off all the gases; cooling after waiting for 5-10 minutes; subsequently, releasing the gases from the vacuum furnace section by section until the pressure in the furnace and the atmospheric pressure are balanced; finally, taking out the workpiece, thereby completing the whole plating process. During the aforesaid process, the water-cooling system of the vacuum furnace operates normally, which allows the temperature in the whole process to be controlled below 50° C., such that the plating process is completed without damaging the plastic workpiece. Additionally, when the workpiece rotates on the hanging rack, the hanging rack rotates in the vacuum furnace, meaning that the rotation and revolution of the workpiece during the plating process are simultaneously achieved. In this way, the workpiece is uniformly plated during the plating process while protected from being damaged by an excessive temperature rise caused by the target's sputtering during the course. Moreover, carbon atoms in residual acetylene gas are removed through extraction, which effectively prevents carbon atoms from attaching to the bactericidal film layer, so that the color of the bactericidal film layer remains unaffected.

In another aspect of the present disclosure, in step (1), the workpiece is cleansed by using a cleaner for plastic or by ultrasonic, the blow-drying temperature does not exceed a temperature of 60° C., and the blow-drying duration is longer than 30 minutes. The workpiece may be cleansed in various ways. Through the cleansing, the surface of the workpiece is kept clean and dry before plating, which may strengthen the binding force of the film layer, and significantly improve the plating quality of the bactericidal film.

In another aspect of the present disclosure, the bias voltage supplied to the metal hanging rack in step (2) is 15V-65V.

In another aspect of the present disclosure, the rotation speed within the vacuum furnace in step (2) is 30 s/r.

In another aspect of the present disclosure, in step (3), the flow rate of argon is 100-250 sccm, the current supplied to the target material is 8 A, and the electroplating duration is 2-10 minutes.

In another aspect of the present disclosure, in step (5), the flow rate of argon is reduced to 40-80 sccm, the flow rate of acetylene gas is 150-250 sccm, and the introduction duration of acetylene gas is 1-5 minutes.

In another aspect of the present disclosure, in step (5), the current supplied to the silver target is 0.5-1 A, and the sputtering duration of the sliver target is 1-4 minutes.

Through adopting the techniques of the present disclosure, the whole process does not need chemical processing, and the film layers are plated without damaging the surface of the plastic workpiece. After plating the binding film layer using a silicon target and nitrogen, the nitrogen is turned off and then a carrier layer is plated using acetylene gas. The large number of silicon atoms contained in the plastic and the silicon atoms in the plated film have good binding force. After the binding film layer and the carrier layer are plated, the carrier layer is kept active and a silver sputtering target is initiated, which enables silver ions with bactericidal effect to be uniformly distributed in the silicon carbide film layer, thereby forming a bactericidal film with bactericidal effect. Additionally, the workpiece is hung on the hanging rack during the plating process, which allows the rotation and revolution of the workpiece to be simultaneously achieved, thus realizing a uniform plating during the target's sputtering while avoiding damage to the workpiece due to local high temperature. Moreover, without the introduction of oxygen during production, the furnace body is protected from being damaged, and the generation of silver oxide caused by the residual oxygen in the furnace during the silver target's sputtering is avoided. The whole process is healthy and eco-friendly. The present disclosure remains the appearance and various properties of plastic, achieves an ideal bactericidal effect, a convenient preparation and a low investment of equipment, and has a wide application range.

### DETAILED DESCRIPTION

Detailed embodiments are combined hereinafter to clearly and completely describe the techniques of the present disclosure. Obviously, the described embodiments are merely a part but not all of the embodiments of the present disclosure. The specification of the present disclosure may allow those skilled in the art to obtain other embodiments without paying creative labor, and thus all of which shall fall into the scope of the present disclosure.

A method for preparing a bactericidal film having a silicon nitride binding layer on plastic, comprising the steps of:

Preprocessing: cleansing a workpiece and blow-drying at a low temperature;

Vacuum processing: hanging the preprocessed workpiece on a hanging rack, and placing into a vacuum furnace; supplying a bias voltage to the metal hanging rack, and vacuuming the furnace to a vacuum degree of 5.0×10⁻³ Pa; initiating a rotating disc, thus making the workpiece rotate on the hanging rack, and simultaneously making the hanging rack rotate within the vacuum furnace;

Plating a binding film layer: switching-on a power supply and regulating the voltage to 30-40V, wherein the duty ratio is 20-30%; introducing argon, thereby enabling the vacuum degree to reach 25×10⁻² Pa; subsequently, initiating a silicon sputtering target, and introducing nitrogen, which enables the vacuum degree to reach 35×10⁻² Pa, thus forming a silicon nitride binding film layer on the surface of the workpiece;

Plating a carrier layer: keeping the silicon target sputtering, turning-off the nitrogen, reducing the flow of argon, and introducing acetylene gas, thus forming a silicon carbide carrier layer on the surface of the workpiece;

Plating a bactericidal film layer: keeping the silicon target sputtering, continuously introducing acetylene gas, and simultaneously initiating a silver sputtering target, thus forming a bactericidal film layer of silicon carbide and silver on the surface of the workpiece;

Completing the film plating: stopping the silicon target and the silver target first, and then turning off all the gases; cooling after waiting for 5-10 minutes; subsequently, releasing the gases from the vacuum furnace section by section until the pressure in the furnace and the atmospheric pressure are balanced; finally, taking out the workpiece, thereby completing the whole plating process. During the aforesaid process, the water-cooling system of the vacuum furnace operates normally, which allows the temperature in the whole process to be controlled below 50° C., such that the plating process is completed without damaging the plastic workpiece. Additionally, when the workpiece rotates on the hanging rack, the hanging rack rotates in the vacuum furnace, meaning that the rotation and revolution of the workpiece during the plating process are simultaneously achieved. In this way, the workpiece is uniformly plated during the plating process while protected from being damaged by an excessive local temperature rise caused by the target's sputtering during the course. Moreover, carbon atoms in residual acetylene gas are removed through extraction, which effectively prevents carbon atoms from attaching to the bactericidal film layer, so that the color of the bactericidal film layer remains unaffected.

In one of the embodiments, in step (1), the workpiece is cleansed by using a cleaner for plastic or by ultrasonic, the blow-drying temperature does not exceed a temperature of 60° C., and the blow-drying duration is longer than 30 minutes. The workpiece may be cleansed in various ways. Through the cleansing, the surface of the workpiece is kept clean and dry before plating, which may strengthen the binding force of the film layer, and significantly improve the plating quality of the bactericidal film.

In one of the embodiments, the bias voltage supplied to the metal hanging rack in step (2) is 15V-65V.

In one of the embodiments, the rotation speed within the vacuum furnace in step (2) is 30 s/r.

In one of the embodiments, in step (3), the flow rate of argon is 100-250 sccm, the current supplied to the target material is 8 A, and the electroplating duration is 2-10 minutes. The thickness of the binding film layer may be controlled through regulating the electroplating duration. A shorter electroplating duration may generate a transparent yellow plating film, and a longer electroplating duration may thicken the film layer, thus making the film layer turn brown and lowering its transparency. The electroplating duration may be controlled according to the actual needs of the products.

In one of the embodiments, in step (5), the flow rate of argon is reduced to 40-80 sccm, the flow rate of acetylene gas is 150-250 sccm, and the introduction duration of acetylene gas is 1-5 minutes.

In one of the embodiments, in step (5), the current supplied to the silver target is 0.5-1 A, and the sputtering duration of the sliver target is 1-4 minutes.

### Embodiment 1

A method for preparing a bactericidal film having a silicon nitride binding layer on plastic, comprising the steps of:

Preprocessing: cleansing a plastic workpiece and blow-drying at a temperature of 60° C. for 45 minutes, wherein the workpiece is cleansed by using a plastic cleaner;

Vacuum processing: hanging the preprocessed workpiece on a hanging rack, and placing into a vacuum furnace; supplying a 15V bias voltage to the metal hanging rack, and vacuuming the furnace to a vacuum degree of 5.0×10⁻³ Pa; subsequently, initiating a rotating disc, thus making the workpiece rotate on the hanging rack, and simultaneously making the hanging rack rotate within the vacuum furnace;

Plating a binding film layer: switching-on a power supply and regulating the voltage to 30V, wherein the duty ratio is 20%; introducing argon with a flow rate of 100 sccm, thereby enabling the vacuum degree to reach 25×10⁻² Pa; subsequently, initiating a silicon sputtering target, and introducing nitrogen, enabling the vacuum degree to reach 35×10⁻² Pa, wherein the current supplied to the silicon target is 8 A, and the electroplating duration is 2 minutes, thus forming a silicon nitride binding film layer on the surface of the workpiece;

Plating a carrier layer: switching-on the power supply and regulating the voltage to 32V, wherein the duty ratio is 25%; keeping the silicon target sputtering, turning-off the nitrogen, reducing the flow rate of argon to 90 sccm, and introducing acetylene gas, enabling the vacuum degree to reach 27×10⁻² Pa, wherein the current supplied to the silicon target is 8 A, and the electroplating duration is 2 minutes, thus forming a silicon carbide carrier layer on the surface of the workpiece;

Plating a bactericidal film layer: keeping the silicon target sputtering, continuously introducing acetylene gas with a flow rate of 90 ccm for 1 minute, and simultaneously initiating a silver sputtering target, thus forming a bactericidal film layer of silicon carbide and silver on the surface of the workpiece, wherein the current supplied to the silver target is 0.5 A, and the sputtering duration of the silver target is 1 minute;

Completing the film plating: stopping the silicon target first, then stopping the silver target, and then turning off all the gases; cooling after waiting for 6 minutes; subsequently, releasing the gases from the vacuum furnace section by section until the pressure in the furnace and the atmospheric pressure are balanced; finally, taking out the workpiece, thereby completing the whole plating process.

### Embodiment 2

A method for preparing a bactericidal film having a silicon nitride binding layer on plastic, comprising the steps of:

Preprocessing: cleansing a plastic workpiece and blow-drying at a temperature of 103° C. for 40 minutes, wherein the workpiece is cleansed by using a plastic cleaner;

Vacuum processing: hanging the preprocessed workpiece on a hanging rack, and placing into a vacuum furnace; supplying a 30V bias voltage to the metal hanging rack, and vacuuming the furnace to a vacuum degree of 5.0×10⁻³ Pa; subsequently, initiating a rotating disc, thus making the workpiece rotate on the hanging rack, and simultaneously making the hanging rack rotate within the vacuum furnace;

Plating a binding film layer: switching-on a power supply and regulating the voltage to 32V, wherein the duty ratio is 25%; introducing argon with a flow rate of 170 sccm, thereby enabling the vacuum degree to reach 25×10⁻² Pa; subsequently, initiating a silicon sputtering target, and introducing nitrogen, enabling the vacuum degree to reach 35×10⁻² Pa, wherein the current supplied to the silicon target is 8 A, and the electroplating duration is 4 minutes, thus forming a silicon nitride binding film layer on the surface of the workpiece;

Plating a carrier layer: switching-on the power supply and regulating the voltage to 32V, wherein the duty ratio is 25%; keeping the silicon target sputtering, turning-off the nitrogen, reducing the flow rate of argon to 90 sccm, and introducing acetylene gas, enabling the vacuum degree to reach 27×10⁻² Pa, wherein the current supplied to the silicon target is 8 A, and the electroplating duration is 2 minutes, thus forming a silicon carbide carrier layer on the surface of the workpiece;

Plating a bactericidal film layer: keeping the silicon target sputtering, continuously introducing acetylene gas with a flow rate of 90 ccm for 1 minute, and simultaneously initiating a silver sputtering target, thus forming a bactericidal film layer of silicon carbide and silver on the surface of the workpiece, wherein the current supplied to the silver target is 0.6 A, and the sputtering duration of the silver target is 1 minute;

Completing the film plating: stopping the silicon target first, then stopping the silver target, and then turning off all the gases; cooling after waiting for 7 minutes; subsequently, releasing the gases from the vacuum furnace section by section until the pressure in the furnace and the atmospheric pressure are balanced; finally, taking out the workpiece, thereby completing the whole plating process.

### Embodiment 3

A method for preparing a bactericidal film having a silicon nitride binding layer on plastic, comprising the steps of:

Preprocessing: cleansing a plastic workpiece and blow-drying at a temperature of 105° C. for 38 minutes, wherein the workpiece is cleansed by using a plastic cleaner;

Vacuum processing: hanging the preprocessed workpiece on a hanging rack, and placing into a vacuum furnace; supplying a 50V bias voltage to the metal hanging rack, and vacuuming the furnace to a vacuum degree of 5.0×10⁻³ Pa; subsequently, initiating a rotating disc, thus making the workpiece rotate on the hanging rack, and simultaneously making the hanging rack rotate within the vacuum furnace;

Plating a binding film layer: switching-on a power supply and regulating the voltage to 34V, wherein the duty ratio is 27%; introducing argon with a flow rate of 200 sccm, thereby enabling the vacuum degree to reach 25×10⁻² Pa; subsequently, initiating a silicon sputtering target, and introducing nitrogen, enabling the vacuum degree to reach 35×10⁻² Pa, wherein the current supplied to the silicon target is 8 A, and the electroplating duration is 6 minutes, thus forming a silicon nitride binding film layer on the surface of the workpiece;

Plating a carrier layer: switching-on the power supply and regulating the voltage to 36V, wherein the duty ratio is 32%; keeping the silicon target sputtering, turning-off the nitrogen, reducing the flow rate of argon to 90 sccm, and introducing acetylene gas, enabling the vacuum degree to reach 27×10⁻² Pa, wherein the current supplied to the silicon target is 8 A, and the electroplating duration is 6 minutes, thus forming a silicon carbide carrier layer on the surface of the workpiece;

Plating a bactericidal film layer: keeping the silicon target sputtering, continuously introducing acetylene gas with a flow rate of 90 ccm for 1 minute, and simultaneously initiating a silver sputtering target, thus forming a bactericidal film layer of silicon carbide and silver on the surface of the workpiece, wherein the current supplied to the silver target is 0.7 A, and the sputtering duration of the silver target is 3 minutes;

Completing the film plating: stopping the silicon target first, then stopping the silver target, and then turning off all the gases; cooling after waiting for 8 minutes; subsequently, releasing the gases from the vacuum furnace section by section until the pressure in the furnace and the atmospheric pressure are balanced; finally, taking out the workpiece, thereby completing the whole plating process.

### Embodiment 4

A method for preparing a bactericidal film having a silicon nitride binding layer on plastic, comprising the steps of:

Preprocessing: cleansing a plastic workpiece and blow-drying at a temperature of 106° C. for 35 minutes, wherein the workpiece is cleansed by using a plastic cleaner;

Vacuum processing: hanging the preprocessed workpiece on a hanging rack, and placing into a vacuum furnace; supplying a 60V bias voltage to the metal hanging rack, and vacuuming the furnace to a vacuum degree of 5.0×10⁻³ Pa; subsequently, initiating a rotating disc, thus making the workpiece rotate on the hanging rack, and simultaneously making the hanging rack rotate within the vacuum furnace;

Plating a binding film layer: switching-on a power supply and regulating the voltage to 36V, wherein the duty ratio is 23%; introducing argon with a flow rate of 230 sccm, thereby enabling the vacuum degree to reach 25×10⁻² Pa; subsequently, initiating a silicon sputtering target, and introducing nitrogen, enabling the vacuum degree to reach 35×10⁻² Pa, wherein the current supplied to the silicon target is 8 A, and the electroplating duration is 8 minutes, thus forming a silicon nitride binding film layer on the surface of the workpiece;

Plating a carrier layer: switching-on the power supply and regulating the voltage to 36V, wherein the duty ratio is 33%; keeping the silicon target sputtering, turning-off the nitrogen, reducing the flow rate of argon to 90 sccm, and introducing acetylene gas, enabling the vacuum degree to reach 27×10⁻² Pa, wherein the current supplied to the silicon target is 8 A, and the electroplating duration is 8 minutes, thus forming a silicon carbide carrier layer on the surface of the workpiece;

Plating a bactericidal film layer: keeping the silicon target sputtering, continuously introducing acetylene gas with a flow rate of 90 ccm for 1 minute, and simultaneously initiating a silver sputtering target, thus forming a bactericidal film layer of silicon carbide and silver on the surface of the workpiece, wherein the current supplied to the silver target is 0.8 A, and the sputtering duration of the silver target is 4 minutes;

Completing the film plating: stopping the silicon target first, then stopping the silver target, and then turning off all the gases; cooling after waiting for 9 minutes; subsequently, releasing the gases from the vacuum furnace section by section until the pressure in the furnace and the atmospheric pressure are balanced; finally, taking out the workpiece, thereby completing the whole plating process.

### Embodiment 5

A method for preparing a bactericidal film having a silicon nitride binding layer on plastic, comprising the steps of:

Preprocessing: cleansing a plastic workpiece and blow-drying at a temperature of 108° C. for 33 minutes, wherein the workpiece is cleansed by using a plastic cleaner;

Vacuum processing: hanging the preprocessed workpiece on a hanging rack, and placing into a vacuum furnace; supplying a 65V bias voltage to the metal hanging rack, and vacuuming the furnace to a vacuum degree of 5.0×10⁻³ Pa; subsequently, initiating a rotating disc, thus making the workpiece rotate on the hanging rack, and simultaneously making the hanging rack rotate within the vacuum furnace;

Plating a binding film layer: switching-on a power supply and regulating the voltage to 38V, wherein the duty ratio is 33%; introducing argon with a flow rate of 270 sccm, thereby enabling the vacuum degree to reach 25×10⁻² Pa; subsequently, initiating a silicon sputtering target, and introducing nitrogen, enabling the vacuum degree to reach 35×10⁻² Pa, wherein the current supplied to the silicon target is 8 A, and the electroplating duration is 2-10 minutes, thus forming a silicon nitride binding film layer on the surface of the workpiece;

Plating a carrier layer: switching-on the power supply and regulating the voltage to 40V, wherein the duty ratio is 35%; keeping the silicon target sputtering, turning-off the nitrogen, reducing the flow rate of argon to 90 sccm, and introducing acetylene gas, enabling the vacuum degree to reach 27×10⁻² Pa, wherein the current supplied to the silicon target is 8 A, and the electroplating duration is 2-10 minutes, thus forming a silicon carbide carrier layer on the surface of the workpiece;

Plating a bactericidal film layer: keeping the silicon target sputtering, continuously introducing acetylene gas with a flow rate of 90 ccm for 1 minute, and simultaneously initiating a silver sputtering target, thus forming a bactericidal film layer of silicon carbide and silver on the surface of the workpiece, wherein the current supplied to the silver target is 1 A, and the sputtering duration of the silver target is 4 minutes;

Completing the film plating: stopping the silicon target first, then stopping the silver target, and then turning off all the gases; cooling after waiting for 10 minutes; subsequently, releasing the gases from the vacuum furnace section by section until the pressure in the furnace and the atmospheric pressure are balanced; finally, taking out the workpiece, thereby completing the whole plating process.

### Embodiment 6

After respectively measuring the film layer binding force of the bactericidal film on each of the plastic workpieces obtained from the aforesaid embodiments 1-5, the measurement results are shown in the following table:

| Embodiment | 1 | 2 | 3 | 4 | 5 |
|---|---|---|---|---|---|
| Binding Force (N) | 63 | 65 | 67.5 | 70 | 72 |

From the above results, it can be seen that, the film layer binding force of the bactericidal film on each of the plastic workpieces obtained through adopting the techniques of the present disclosure is greater than 60N, which indicates that the film layer binding force is strong enough to meet the requirements of ordinary plastic products.

### Embodiment 7

The plastic workpieces obtained from embodiments 1-5 are all mobile screens made of the same material, which are respectively numbered as groups 1-5, and a conventional mobile screen made of the same material is taken as a comparison group. The number of bacterial colonies on the surface of the six groups of samples is respectively observed after 5, 7 and 10 hours under the same using condition. The results are shown in the following table:

| | | | | | | Comparison |
|---|---|---|---|---|---|---|
| Samples | Group 1 | Group 2 | Group 3 | Group 4 | Group 5 | Group |
| 5 hours | 8 | 9 | 10 | 7 | 6 | 40 |
| (number/ | | | | | | |
| cm²) | | | | | | |
| 7 hours | 1 | 4 | 5 | 3 | 2 | 53 |
| (number/ | | | | | | |
| cm²) | | | | | | |
| 10 hours | 0 | 0 | 0 | 0 | 0 | 70 |
| (number/ | | | | | | |
| cm²) | | | | | | |

From the above results, it can be seen that the bactericidal film of the present disclosure significantly improves the bactericidal effect of the mobile screen and thus possesses a high practical value.

The above is merely a description of preferred embodiments of the present disclosure, which cannot be understood as a limitation of the claims. Any equivalent modifications of the structure or process described in the specification of the present disclosure shall fall into the scope of the present disclosure.

What is claimed is:

1. A method for preparing a bactericidal film having a silicon nitride binding layer on plastic, comprising:
cleansing and blow-drying a workpiece;
processing the workpiece with a vacuum furnace, wherein processing the workpieces with the vacuum furnace comprises:
hanging the preprocessed workpiece on a hanging rack and placing the hanging rack into the vacuum furnace,
supplying a bias voltage to the metal hanging rack and vacuuming the furnace to a vacuum degree of 5.0×10⁻³ Pa, and
initiating a rotating disc to make the workpiece rotates on the hanging rack and simultaneously making the hanging rack rotates within the vacuum furnace;
plating a bactericidal film interface layer on the workpiece, wherein plating the bactericidal film interface layer comprises:
switching-on a power supply and regulating the voltage to 30-40V, duty ratio is configured to control the power supply, wherein the duty ratio is 20-30%,
enabling the vacuum degree to reach 25×10⁻² Pa by introducing argon at a first flow rate, and
forming a silicon nitride binding film layer on the surface of the workpiece by initiating a silicon sputtering target and introducing nitrogen to enable the vacuum degree to reach 35×10⁻² Pa;
forming a silicon carbide carrier layer on the surface of the workpiece by keeping the silicon sputtering target sputtering, turning-off the nitrogen, introducing the argon at a second flow rate, and introducing acetylene gas at a third flow rate;
forming a bactericidal film layer of silicon carbide and silver on the surface of the workpiece by keeping the silicon sputtering target sputtering, continuously introducing the acetylene gas, and simultaneously initiating a silver sputtering target; and
completing the bactericidal film, wherein completing the bactericidal film comprises:
stopping the silicon sputtering target first, then stopping the silver sputtering target, and then turning off all gases;
cooling after waiting for 5 minutes to 10 minutes;
releasing the gases from the vacuum furnace section by section until pressure in the furnace and atmospheric pressure are balanced; and
taking out the workpiece.

2. The method for preparing a bactericidal film having a silicon nitride binding layer on plastic of claim 1, wherein cleansing and blow-drying the workpiece comprises:
cleansing the workpiece using a cleaner for plastic or by ultrasonic, and
blow-drying the workpiece at a blow-drying temperature not exceeding 60° C. with a blow-drying duration longer than 30 minutes.

3. The method for preparing a bactericidal film having a silicon nitride binding layer on plastic of claim 1, wherein the bias voltage is between 15V to 65V.

4. The method for preparing a bactericidal film having a silicon nitride binding layer on plastic of claim 1, wherein the rotating disc rotates at a rotation speed of 30 s/r.

5. The method for preparing a bactericidal film having a silicon nitride binding layer on plastic of claim 1, wherein the first flow rate is between 100 sccm to 250 sccm, wherein initiating the silicon sputtering target comprises supplying a first current at 8 A to the silicon sputtering target, and wherein plating the bactericidal film interface layer further comprises electroplating the bactericidal film interface layer between 2 minutes to 10 minutes.

6. The method for preparing a bactericidal film having a silicon nitride binding layer on plastic of claim 1, wherein the second flow rate is between 40 sccm to 80 sccm, wherein the third flow rate is between 150 sccm to 250 sccm, wherein introducing acetylene gas at the third flow rate comprises introducing the acetylene gas with an introduction duration between 1 minute to 5 minutes.

7. The method for preparing a bactericidal film having a silicon nitride binding layer on plastic of claim 1, wherein initiating the silver sputtering target comprises supplying a second current between 0.5 A to 1 A to the silver sputtering target with a sputtering duration between 1 minute to 4 minutes.
